(19) United States
(12) Patent Application Publication
(10) Pub. No.: US 2010/0031130 A1
(43) Pub. Date: Feb. 4, 2010

(54) FORWARD ERROR CORRECTION (FEC) AND VARIABLE LENGTH CODE (VLC) JOINT DECODING

(75) Inventors: YANBIN YU, FREMONT, CA (US); LIN YANG, FREMONT, CA (US)

Correspondence Address: FRANK F. TIAN, 331-4A THIRD AVENUE, LONG BEACH, NJ, 07740, US

(73) Assignee: LEGEND SILICON CORP., FREMONT, CA (US)

(21) Appl. No.: 12/185,526

(22) Filed: Aug. 4, 2008

(51) Int. Cl. H03M 13/03; G06F 11/07

(52) U.S. Cl. 714/796; 714/E11.023

(57) ABSTRACT

A method for decoding is provided. The method comprises the step of: using information known to a channel decoder to determine a path between two data points, whereby reducing error or bad data effects.

### CROSS-REFERENCE TO OTHER APPLICATIONS

The following applications of common assignee and filed on the same day herewith are related to the present application, and are herein incorporated by reference in their entireties:

U.S. patent application Ser. No. ______ with attorney docket number LSFFT-112.

### FIELD OF THE INVENTION

The present invention relates generally to an application in a digital television system, more specifically the present invention relates to forward error correction (FEC) and Variable Length Code (VLC) joint decoding.

### BACKGROUND

Digital television (DTV) receivers can receive signal either on a fix point basis, or on a mobile basis. The DTV that receives on the mobile basis or in the wireless environment pose challenges. The challenges include that in the mobile environment, receiving conditions such as signal noise ratio (SNR) and bit error ratio (BER) fluctuate significantly. As a result, the final bit streams can be erroneous from time to time and have some obvious gaps in the seconds range (˜1 s) when the users are temporally blacked out (e.g. a mobile device in a automobile driving through a freeway underpass) even though the average signal strength and SNR are good. This is especially true in the case when interleaving memory is not really big enough to overcome the issue in single carrier communications systems in such cases as ATSC DTV signals.

Therefore, it is desirous to use information on bad data generated by channel decoder to determine a best path to overcome bad data in a coding context.

### SUMMARY OF THE INVENTION

A method for decoding is provided. The method comprises the step of: using information known to a channel decoder and providing the information to a source decoder to determine a path between two data points, whereby reducing error or bad data effects.

### BRIEF DESCRIPTION OF THE FIGURES

The accompanying figures, where like reference numerals refer to identical or functionally similar elements throughout the separate views and which together with the detailed description below are incorporated in and form part of the specification, serve to further illustrate various embodiments and to explain various principles and advantages all in accordance with the present invention.

FIG. 1 is an example of a bit stream in accordance with some embodiments of the invention.

FIG. 2 is an example of a path selection method in accordance with some embodiments of the invention.

FIG. 3 is an example of some outcomes in accordance with some embodiments of the invention.

FIG. 4 is an example of a flowchart in accordance with some embodiments of the invention.

Skilled artisans will appreciate that elements in the figures are illustrated for simplicity and clarity and have not necessarily been drawn to scale. For example, the dimensions of some of the elements in the figures may be exaggerated relative to other elements to help to improve understanding of embodiments of the present invention.

### DETAILED DESCRIPTION

Before describing in detail embodiments that are in accordance with the present invention, it should be observed that the embodiments reside primarily in combinations of method steps and apparatus components related to power estimation for uplink or downlink using channel decoder to determine a best path to overcome bad data or error in a coding context. Accordingly, the apparatus components and method steps have been represented where appropriate by conventional symbols in the drawings, showing only those specific details that are pertinent to understanding the embodiments of the present invention so as not to obscure the disclosure with details that will be readily apparent to those of ordinary skill in the art having the benefit of the description herein.

In this document, relational terms such as first and second, top and bottom, and the like may be used solely to distinguish one entity or action from another entity or action without necessarily requiring or implying any actual such relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element proceeded by “comprises . . . a” does not, without more constraints, preclude the existence of additional identical elements in the process, method, article, or apparatus that comprises the element.

It will be appreciated that embodiments of the invention described herein may be comprised of one or more conventional processors and unique stored program instructions that control the one or more processors to implement, in conjunction with certain non-processor circuits, some, most, or all of the functions of using known sequences within the guard intervals being used for power estimation for uplink or downlink using channel decoder to determine a best path to overcome bad data or error in a coding context. The non-processor circuits may include, but are not limited to, a radio receiver, a radio transmitter, signal drivers, clock circuits, power source circuits, and user input devices. As such, these functions may be interpreted as steps of a method to power estimation for uplink or downlink using channel decoder to determine a best path to overcome bad data or error in a coding context. Alternatively, some or all functions could be implemented by a state machine that has no stored program instructions, or in one or more application specific integrated circuits (ASICs), in which each function or some combinations of certain of the functions are implemented as custom logic. Of course, a combination of the two approaches could be used. Thus, methods and means for these functions have been described herein. Further, it is expected that one of ordinary skill, notwithstanding possibly significant effort and many design choices motivated by, for example, available time, current technology, and economic considerations, when guided by the concepts and principles disclosed herein will be readily capable of generating such software instructions and programs and ICs with minimal experimentation.

Channel decoder such as the Forward Error Correction (FEC) decoder furnishes code information, code position, and possible candidates. The present invention comprises a method for source-channel decoding that makes use of the information, the position, and possible candidates of the code. The source decoder take advantage of VLC (Variable Length Code)'s uniqueness of the path to find a good path, and therefore to recover the error produced and known in the channel decoding process. If the path cannot be easily found or multiple paths are possible, the source decoder can always avoid the bad bits and conceal them using neighboring data, which is disclosed in the sister patent application having attorney reference number LSFFT-112 and is hereby incorporated herein by reference.

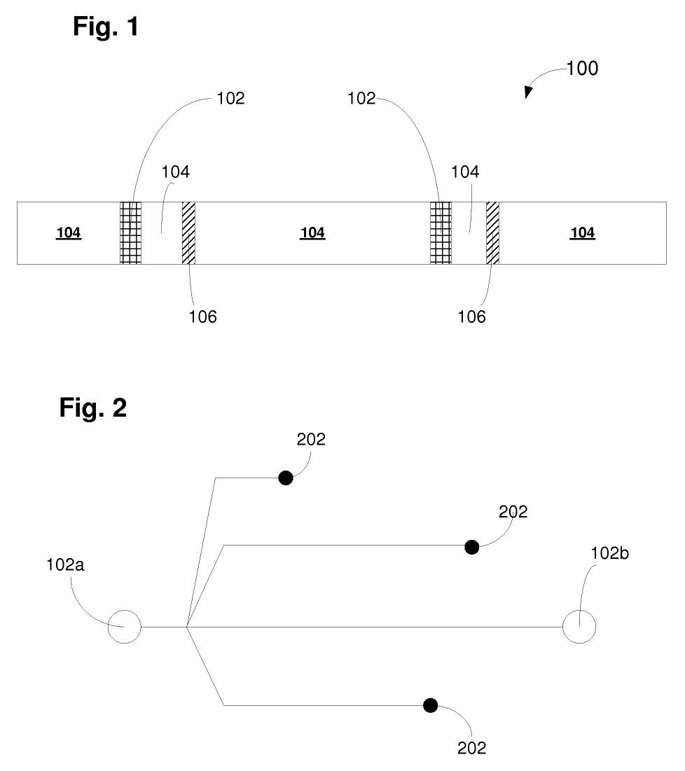

Referring to FIG. 1, a bit stream 100 in accordance with some embodiments of the invention is shown. Bit stream 100 comprises a multiplicity of start codes 102 distributed therein for demarcation or synchronization purposes. Bit stream 100 further comprises good data 104 and bad data or error 106. Between two adjacent start codes 102, there may exist bad data or error 106. The present invention provides a means for locating and addressing the bad data or error 106 issue such that a viewer (not shown) or a user may be less likely to perceive the effect of the bad data or error 106.

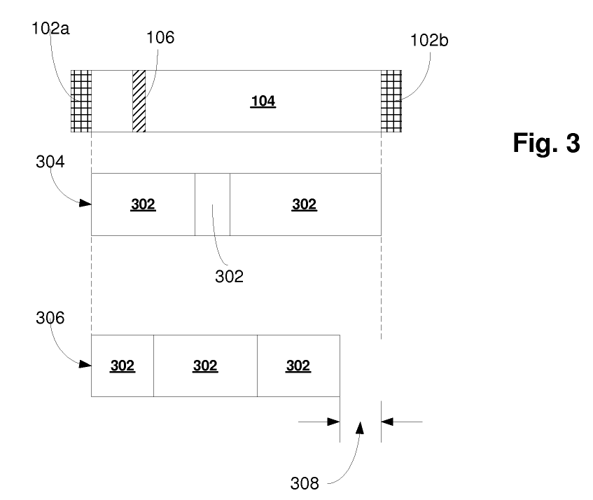

Referring to FIG. 2, a path selection method 200 is shown. a method or system 300 for realizing the path C is shown. In the process of decoding a bitstream, the startcode (SC) 102a, which is composed twenty-three (23) zeros and a single one (1) in the context of MPEG-1 and MPEG-2 is used to mark the start of a slice of macro-blocks. The same SC is used to synchronize the decoding process. When an error is encountered in decoding of VLC with the error position known, the possibilities of solving the problem may be four (4) for example and denoted by four paths, i.e. path A, path B, path C, and path C. Each path can be evaluated to see if the next start code 102b can be correctly reached. The paths that are terminated 202 early will be eliminated during the process of decoding. Since VLC is used, it is possible to find a unique path to reach the re-synchronization point (SC). See FIG. 3 for further descriptions.

Referring to FIG. 3, a startcode (SC) 102a and a next start code 102b subsequent to start code 102a is provided having bad data or error 106 among good data 104. A number of paths having a multiplicity of sub-blocks of data 302 with known length can be evaluated to see if the next start code 102b can be correctly reached. Sub-blocks of data 302 represents the variable length (VLC) code. Path 304, upon evaluation, terminates to the next start code 102b and will be used. Path 306 terminated early with a gap 308 between the last block 302 and next start code 102b, thereby will be eliminated during the process of decoding. The present invention uses FEC (RS code or other error correction code codes) and variable length code (VLC) together to correct the errors. Other error correction codes comprise Turbo codes, low-density parity-check code (LDPC code, Concatenate FEC codes, and the like.

If bad data or error 106 or fault is found by a channel decoder such as a FEC decoder and the coding is VLC, the present method or system 300 can be used to achieve a unique outcome.

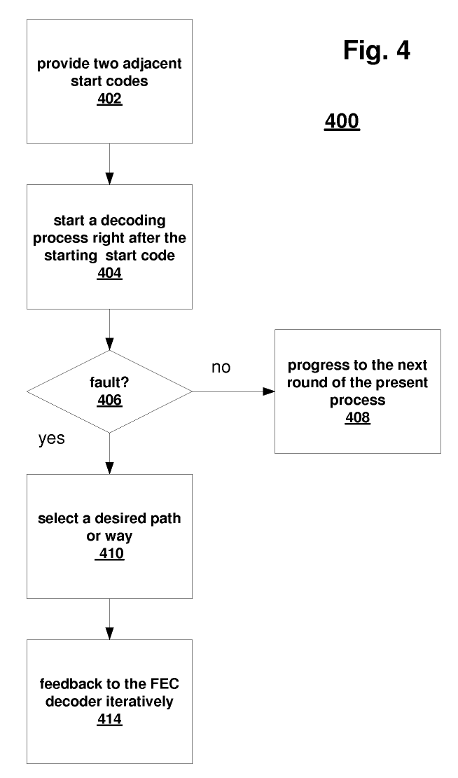

Referring to FIG. 4, a flowchart 400 for in accordance with some embodiments of the invention is shown. Initially two adjacent start codes 102 are provided (Step 402). Among the two adjacent start codes 102, we denote a starting start code 102a and a subsequent or ending start code 102b. a channel decoder knows beforehand at least one location of error between the two adjacent start codes 102. A decoding process is performed right after the starting start code 102a and progress stepwise toward the subsequent or ending start code 102b using information given by a channel decoder such as a look-up-table (LUT) of FEC (Step 404). Determine whether there is a fault based upon the information given by a channel decoder (Step 406). If there is no fault, go directly toward the subsequent start code 102 and using same as the starting start code 102 for the next round of the present process (Step 410). If there is fault, the method described in FIGS. 2-3 is used and a desired path or way is selected to correct the errors (Step 412). Furthermore, the result may feedback to the FEC decoder iteratively to improve performance (Step 414).

In the Forward Error Correction context, the output bitstreams of the FEC will be consumed by a source decoder or a multi-media decoder such as MPEG video decoder. In the MPEG context, for example MPEG2, syntax is normally composed of FLC (Fixed Length Code) and VLC (Variable Length Code). The majority of coded picture elements such as Motion Vectors and DCT coefficients are normally coded by the VLC. By combining the VLC and FEC like Reed-Solomon Code, performance is improved in the area of the error resistance for the whole system. Sometimes, FEC decoder cannot eliminate all the bad data or error but knows some information of the bad data or error such as the position of the bad data or error. Therefore, it is advantageous to use the information known to the FEC decoder to further eliminate the effect of the bad data or error. In other words, if the error locations informed by the FEC decoder can be used to find a good guess using VLC to weight possible solution for the error. The errors in turn are corrected (See FIGS. 2-4. Further, the solution or the selected path may further be used with FEC code iteratively to improve the performance.

Whenever, the position of the error is known the method described above can be used. Since, the majority of the bitstream is made of VLC, such method can be widely used to reduce the bits error rate in the video. There may be situations where the present method cannot solve in that error 106 is still processed without the advantage of the present invention.

In the foregoing specification, specific embodiments of the present invention have been described. However, one of ordinary skill in the art appreciates that various modifications and changes can be made without departing from the scope of the present invention as set forth in the claims below. Accordingly, the specification and figures are to be regarded in an illustrative rather than a restrictive sense, and all such modifications are intended to be included within the scope of present invention. The benefits, advantages, solutions to problems, and any element(s) that may cause any benefit, advantage, or solution to occur or become more pronounced are not to be construed as a critical, required, or essential features or elements of any or all the claims. The invention is defined solely by the appended claims including any amendments made during the pendency of this application and all equivalents of those claims as issued.

Terms and phrases used in this document, and variations thereof, unless otherwise expressly stated, should be construed as open ended as opposed to limiting. As examples of the foregoing: the term “including” should be read as mean “including, without limitation” or the like; the term “example” is used to provide exemplary instances of the item in discussion, not an exhaustive or limiting list thereof; and adjectives such as “conventional,” “traditional,” “normal,” “standard,” and terms of similar meaning should not be construed as limiting the item described to a given time period or to an item available as of a given time, but instead should be read to encompass conventional, traditional, normal, or standard technologies that may be available now or at any time in the future. Likewise, a group of items linked with the conjunction “and” should not be read as requiring that each and every one of those items be present in the grouping, but rather should be read as “and/or” unless expressly stated otherwise. Similarly, a group of items linked with the conjunction “or” should not be read as requiring mutual exclusivity among that group, but rather should also be read as “and/or” unless expressly stated otherwise.

What is claimed is:

1. A method for decoding comprising the step of:
using information known to a channel decoder and providing same to a source decoder to determine a path between two data points, whereby reducing error or bad data effects.

2. The method of claim 1 further comprising the step of using the determined path for further channel decoding.

3. The method of claim 1, wherein the information comprises at least one bad data location or position known to the channel decoder.

4. The method of claim 1, wherein the channel decoder comprises a forward error correction (FEC) decoder using Reed-Solomon (RS) code, low density parity check (LDPC) code, or other types of error correction codes.

5. The method of claim 1, wherein the path spans over sub-blocks of data.

6. The method of claim 1, wherein the two data points comprise a first start code and a second start code subsequence to the first start code.

7. The method of claim 1, wherein variable length code (VLC) in a bit stream for decoding.
